(19) United States
(12) Patent Application Publication
(10) Pub. No.: US 2024/0170545 A1
(43) Pub. Date: May 23, 2024

(54) AIRGAP SPACER AND LOCAL INTERCONNECT CONFIGURATION WITH DIRECT BACKSIDE CONTACT

(71) Applicant: International Business Machines Corporation, Armonk, NY (US)

(72) Inventors: Ruilong Xie, Niskayuna, NY (US); Lawrence A. Clevenger, Saratoga Springs, NY (US); Nicholas Anthony Lanzillo, Wynantskill, NY (US); Huai Huang, Clifton Park, NY (US); Hosadurga Shobha, Niskayuna, NY (US)

(21) Appl. No.: 18/056,416

(22) Filed: Nov. 17, 2022

(51) Int. Cl. H01L 29/417; H01L 21/8238; H01L 27/092; H01L 29/06; H01L 29/423; H01L 29/66; H01L 29/775

(52) U.S. Cl. CPC H01L 29/41733; H01L 21/823807; H01L 21/823871; H01L 27/092; H01L 29/0673; H01L 29/42392; H01L 29/66439; H01L 29/775

(57) ABSTRACT

Embodiments of the invention include a transistor having a first source/drain region and a second source/drain region on opposite sides of the transistor, the first source/drain region being below an airgap spacer and electrically connected to a front side of the transistor, the second source/drain region being adjacent to a solid spacer and electrically connected to a backside of the transistor. The front side is above the transistor, and the backside is below the transistor

### BACKGROUND

The present invention generally relates to fabrication methods and resulting structures for integrated circuits (ICs), and more specifically, to fabrication methods and resulting structures configured and arranged to provide an airgap spacer local interconnect configuration with a direct backside contact.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing fabrication methods and resulting structures for an airgap spacer and local interconnect configuration with a direct backside contact. A non-limiting method includes providing a transistor having a first source/drain region and a second source/drain region on opposite sides of the transistor, where the first source/drain region is below an airgap spacer and electrically connected to a front side of the transistor. The method includes configuring the second source/drain region to be adjacent to a solid spacer and electrically connected to a backside of the transistor. The front side is above the transistor, and the backside is below the transistor.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, and 1C respectively depict a top view and cross-sectional views of a portion of an integrated circuit (IC) under-fabrication after fabrication operations according to one or more embodiments of the invention;

FIGS. 2A, 2B, and 2C respectively depict a top view and cross-sectional views of a portion of an IC under-fabrication after fabrication operations according to one or more embodiments of the invention;

FIGS. 3A, 3B, and 3C respectively depict a top view and cross-sectional views of a portion of an IC under-fabrication after fabrication operations according to one or more embodiments of the invention;

FIGS. 4A, 4B, and 4C respectively depict a top view and cross-sectional views of a portion of an IC under-fabrication after fabrication operations according to one or more embodiments of the invention;

FIGS. 5A, 5B, and 5C respectively depict a top view and cross-sectional views of a portion of an IC under-fabrication after fabrication operations according to one or more embodiments of the invention;

FIGS. 6A, 6B, and 6C respectively depict a top view and cross-sectional views of a portion of an IC under-fabrication after fabrication operations according to one or more embodiments of the invention;

FIGS. 7A, 7B, and 7C respectively depict a top view and cross-sectional views of a portion of an IC under-fabrication after fabrication operations according to one or more embodiments of the invention;

FIGS. 8A, 8B, and 8C respectively depict a top view and cross-sectional views of a portion of an IC under-fabrication after fabrication operations according to one or more embodiments of the invention;

FIGS. 9A, 9B, and 9C respectively depict a top view and cross-sectional views of a portion of an IC under-fabrication after fabrication operations according to one or more embodiments of the invention;

FIGS. 10A, 10B, and 10C respectively depict a top view and cross-sectional views of a portion of an IC under-fabrication after fabrication operations according to one or more embodiments of the invention;

FIGS. 11A, 11B, and 11C respectively depict a top view and cross-sectional views of a portion of an IC under-fabrication after fabrication operations according to one or more embodiments of the invention;

FIGS. 12A, 12B, and 12C respectively depict a top view and cross-sectional views of a portion of an IC under-fabrication after fabrication operations according to one or more embodiments of the invention;

FIGS. 13A, 13B, and 13C respectively depict a top view and cross-sectional views of a portion of an IC under-fabrication after fabrication operations according to one or more embodiments of the invention; and

FIG. 14 is a flowchart of a computer-implemented method of forming an airgap spacer and local interconnect configuration with a direct backside contact according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

One or more embodiments provide fabrication methods and resulting structures for an airgap spacer and local interconnect configuration with a direct backside contact. A semiconductor device is fabricated to include a transistor with a spacer having an airgap on one side, and an adjacent source/drain epitaxial region next to the airgap spacer is wired to the back-end-of-line (BEOL) at frontside. The spacer at the other side of the transistor is a solid spacer having no airgap, and the adjacent source/drain epitaxial region next to the solid spacer is wired to the backside power delivery network (BSPDN). A local interconnect is formed over and/or adjacent to the solid spacer, and underneath there is a backside contact in contact with the source/drain epitaxial region. A metal layer (e.g., M1 line) is over but not in direct contact and not in electrical contact with the local interconnect. One source/drain epitaxial region of the first complimentary metal-oxide-semiconductor (CMOS) cell is wired to metal layer lines (e.g., M1 lines) over the second CMOS cell by the local interconnect. A filled conductive via (e.g., V0) over the frontside source/drain contact has a symmetric shape, while the filled conductive via (e.g., V0′) over the local interconnect has an asymmetric shape.

There are various technical benefits and solutions, according to one or more embodiments. The airgap spacer is used to reduce parasitic capacitance between the source/drain contact and gate. Having a direct backside contact frees some space in one cell which can be used by a neighboring cell connected to the local interconnect. Moreover, the airgap spacer is not formed between backside contact and the gate, because a solid spacer is used instead, thereby avoiding any potential short circuit concern with the local interconnect and gate through the airgap spacer. Further, the local interconnect can fly over the backside contact for flexible routing across the cell boundary of the first and second CMOS cells.

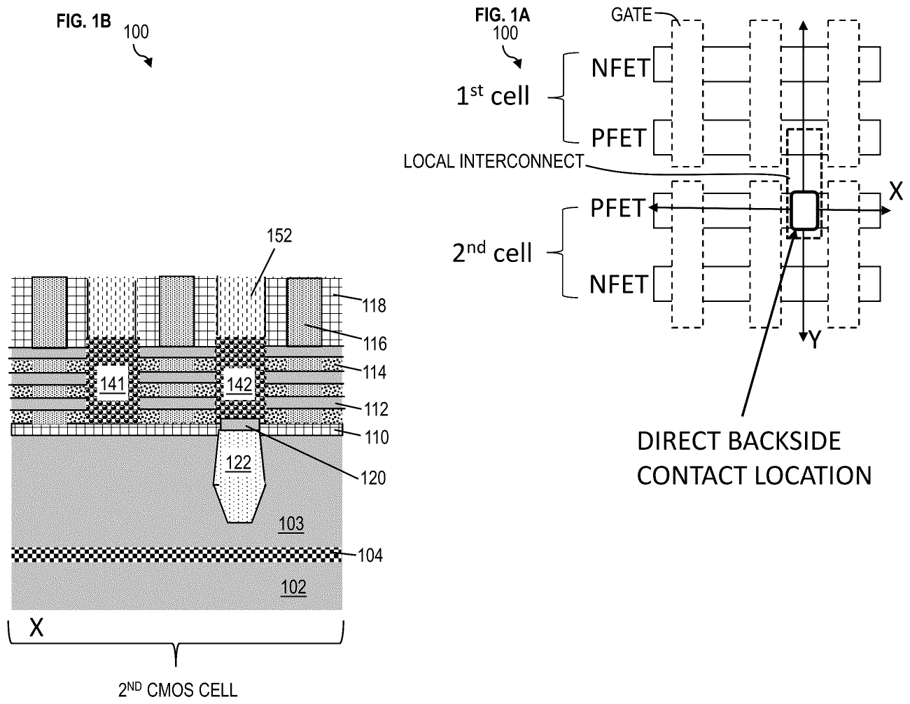

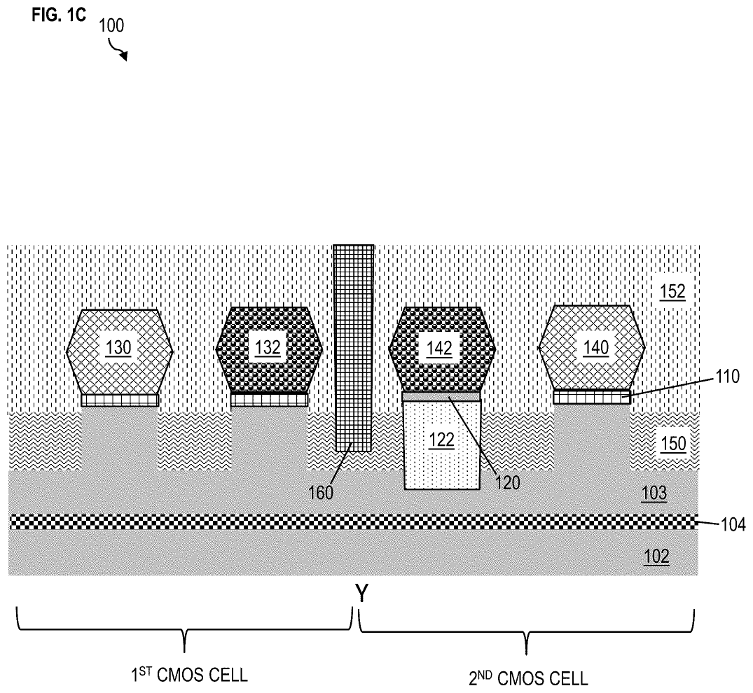

Turning now to a more detailed description of aspects of the present invention, FIG. 1A depicts a top view of a simplified illustration of a portion of an integrated circuit (IC) 100, FIG. 1B depicts a cross-sectional view taken along X of the IC 100, FIG. 1C depicts a cross-sectional view taken along Y of the IC 100. For ease of understanding, some layers may be omitted from the various top views so as not to obscure the figure and to view layers underneath. As such, the top view is intended to provide a simplified illustration and a general orientation. Standard semiconductor fabrication techniques can be utilized to fabricate IC 100 as understood by one of ordinary skill in the art. Any suitable lithography processes including deposition techniques and etching techniques can be utilized herein.

FIGS. 1A, 1B, and 1C depict the IC 100 having a wafer where several fabrication processes have been performed. A nanosheet stack is formed is formed on a substrate 102 and 103, which has an etch stop layer 104 separating the substrates 102 and 103. The wafer or substrates 102, 103 may be formed of (pure) silicon. Other suitable materials can be utilized for the substrates 102, 103. The etch stop layer can be a silicon germanium (SiGe) layer. In other embodiments, the etch stop layer can be silicon dioxide (SiO₂).

The nanosheet stack includes layers 112 formed above substrates 102, 103. The layers 112 are semiconductor material and may be substantially pure silicon. The layers 112 are as the channel regions for the FET device. Inner spacers 114 separate the layers 112 in the nanosheet stack. Example materials of the inner spacers 114 may include SiBCN, SiOCN, SiN, SiOC, SiC, etc.

Source/drain epitaxial regions 130, 132 and source/drain regions 140, 141, 142 are connected to the ends of the layers 112 in the first CMOS cell and second CMOS cell, respectively. The source/drain epitaxial regions 132, 141, 142 may be P-type epitaxial material, resulting in P-type source and drain regions. The source/drain epitaxial regions 130, 140 may be N-type epitaxial material, resulting in N-type source and drain regions. At least one of the source/drain regions is formed to sit directly on a sacrificial placeholder 122. In this example, source/drain epitaxial region 142 sits on the sacrificial placeholder 122 in the second CMOS cell. In one or more embodiments, one or more additional source/drain epitaxial regions may sit on their own sacrificial placeholders. A buffer layer 120 may separate the source/drain epitaxial region 142 from the sacrificial placeholder 122. The buffer layer 120 is in direct contact with the source/drain epitaxial region 142. In one or more embodiments, the buffer layer 120 may not be present. Example materials of the sacrificial placeholder 122 may include SiGe, III-V semiconductors, TiOx, AlOx, etc. The buffer layer 120 may be silicon.

The nanosheet stack of layers 112 is separated from the substrate 103 by a bottom dielectric isolation layer 110 formed under the nanosheet stack. Gate spacers 118 are formed on the sides of a gate structure 116. Gate spacer material is utilized to form the bottom dielectric isolation layer 110 and the gate spacers 118. Example materials of the gate spacer material and bottom dielectric isolation layer may include SiN, SiBCN, SiOCN, SiOC, etc. The gate structure 116 includes a high-k dielectric material formed on the layers 112 followed by one or more work function material layers.

Shallow trench isolation (STI) regions 150 are formed in the substrate 103. The STI regions 150 may include one or more dielectric materials such as SiO₂. The STI regions 150 may include a low-k or ultralow-k dielectric material. A gate cut region 160 is formed through interlayer dielectric (ILD) material 152 and into part of the STI region 150. The gate cut region 160 includes a dielectric material and example materials may include SiN, SiBCN, SiOCN, SiOC, SiC, SiO₂, etc. The ILD material 152 can include SiN, SiO₂, or low-k materials and ultralow-k materials with k-value<4.

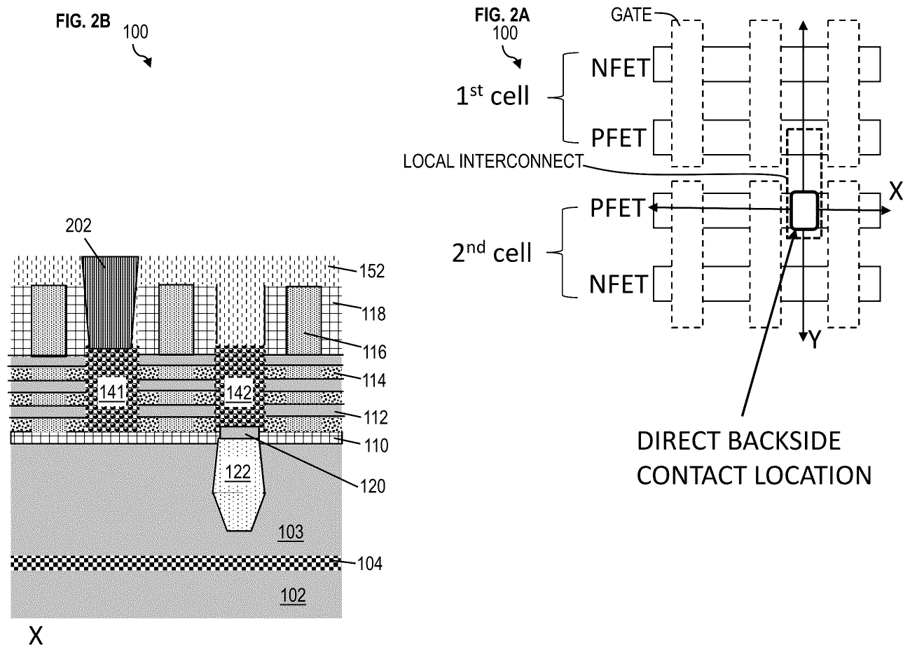

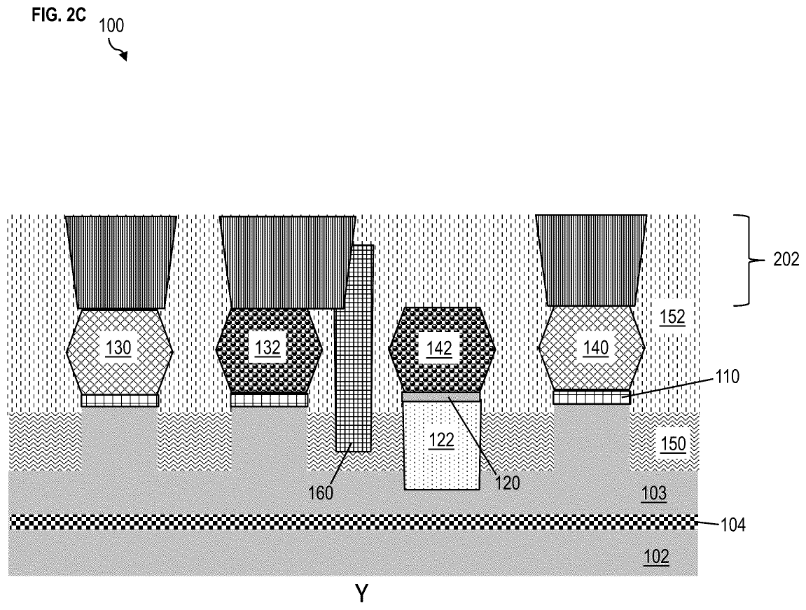

FIGS. 2A, 2B, and 2C depict the IC 100 after middle-of-line (MOL) processing. Contact formation is performed for MOL contacts, resulting in metal contacts 202. For example, further ILD material 152 is deposited, source/drain contact openings are patterned by conventional lithography and etching process, and then metal is deposited to fill the cavities thereby forming the metal contacts 202. A portion of the metal contacts may include silicide, resulting from the interface of the metal material and semiconductor material. The metal contacts 202 are source/drain contacts that are respectively connected to source/drain epitaxial regions 130, 132, 140, 141. As can be seen, no metal contact is in contact with the top side of the source/drain epitaxial region 142.

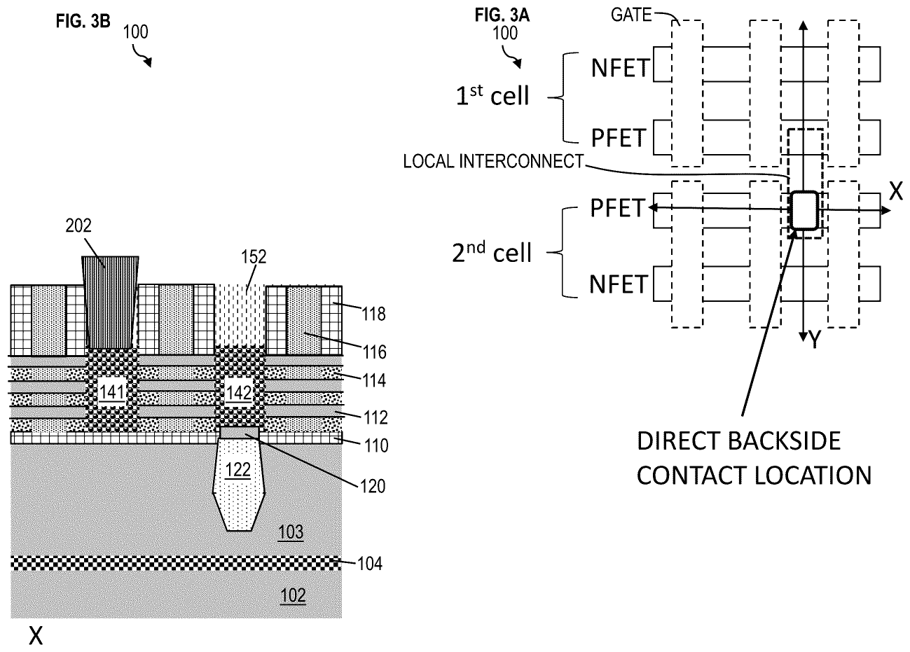

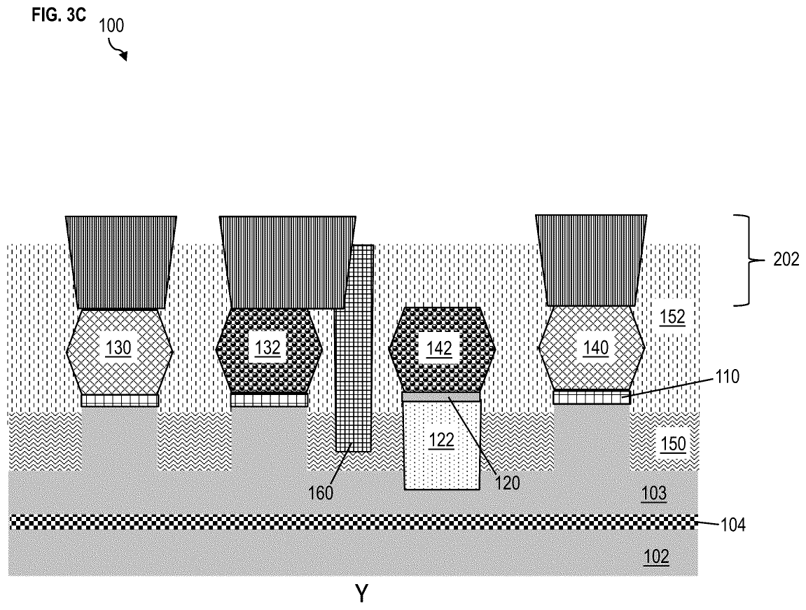

FIGS. 3A, 3B, and 3C depict the IC 100 after interlayer dielectric recess. As can be seen, a portion of the ILD material 152 is recessed to expose the gate spacers 118.

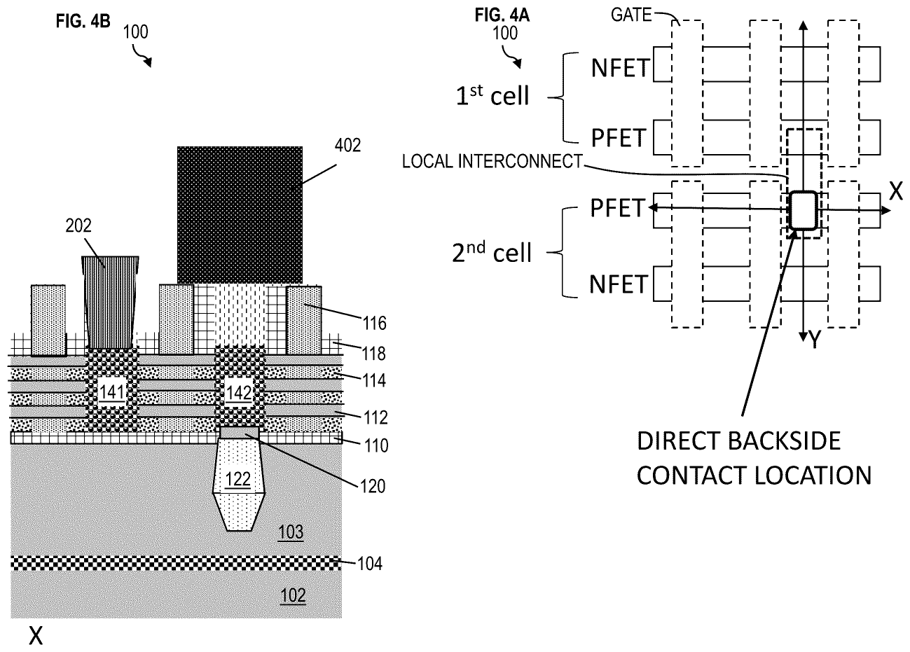

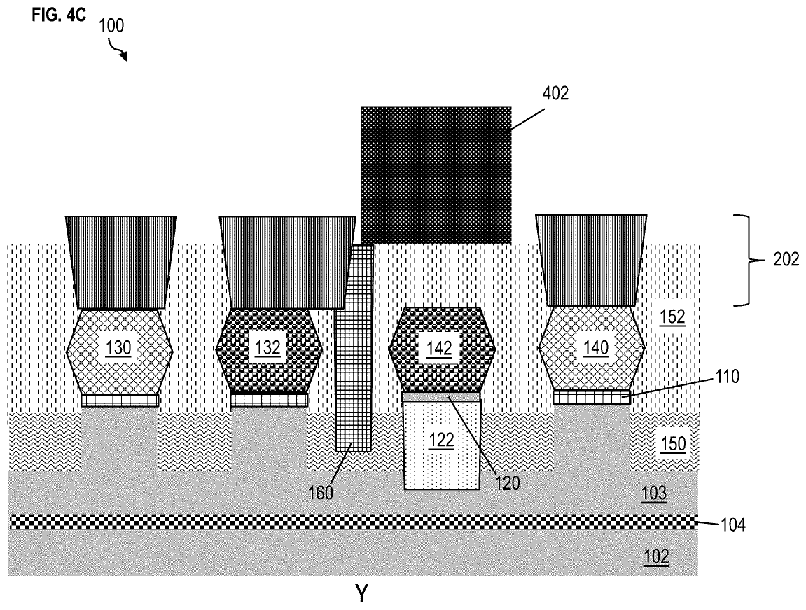

FIGS. 4A, 4B, and 4C depict the IC 100 after gate spacer recess. A mask layer 402 is deposited and etched. The mask layer 402 may be an organic patterning layer (OPL) and/or any suitable material or combination of materials. An anisotropic etch may be utilized to etch the mask layer 402. Using the patterned mask layer 402 as a mask to protect the direct backside contact region, further etching is performed to recess portions of the gate spacer 118.

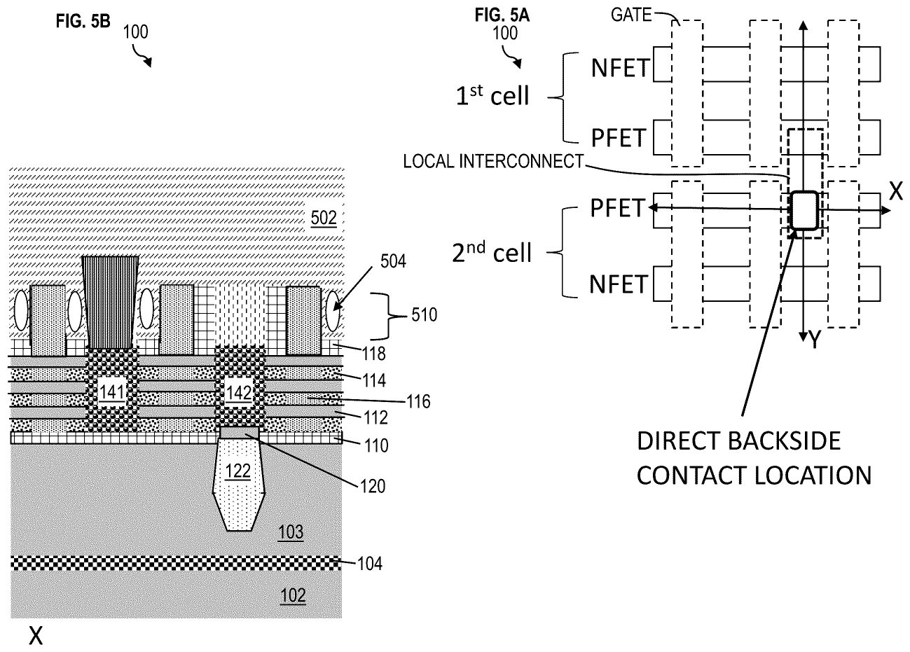

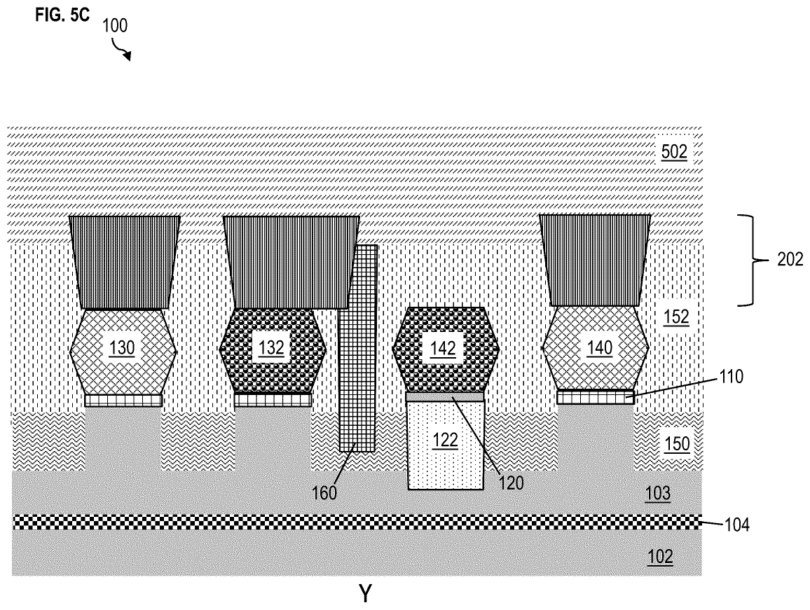

FIGS. 5A, 5B, and 5C depict the IC 100 after airgap spacer formation. The mask layer 402 is removed, for example, by ashing the OPL. A non-conformal dielectric deposition of ILD material 502 is performed to form airgap spacer 510 with airgaps 504. The airgap spacers 510 with airgaps 504 are on the sides of the gate structures 116. However, in the direct backside contact region, the solid filled gate spacers 118 are at the full height of the gate structure 116 and no airgaps 504 are present. Example materials of the airgap spacer 510 may include a SiO₂, SiN, SiOC, or low-k oxide material with k value <4. The airgap spacer 510 may include a low-k dielectric material or an ultralow-k dielectric material.

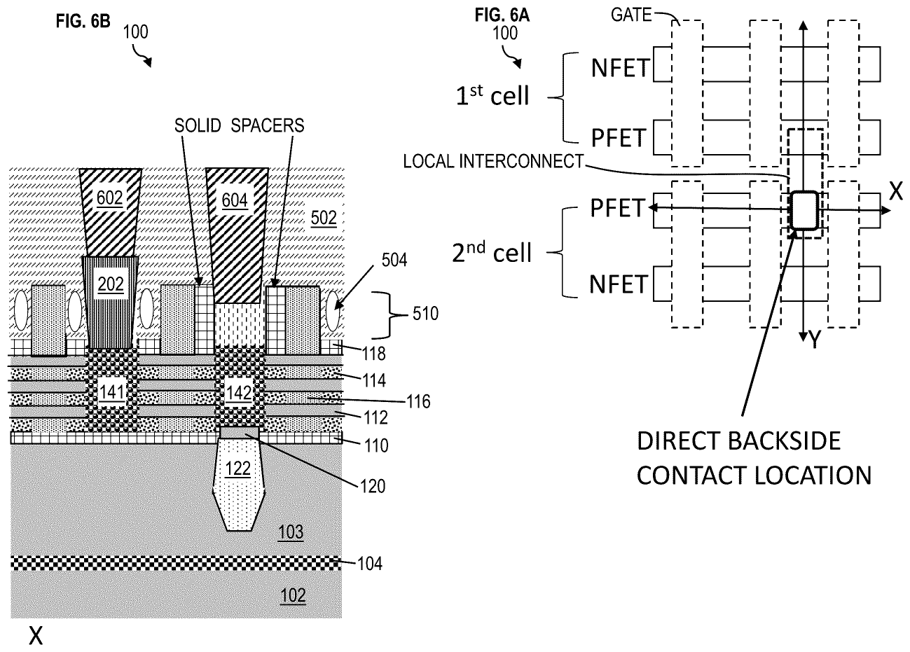

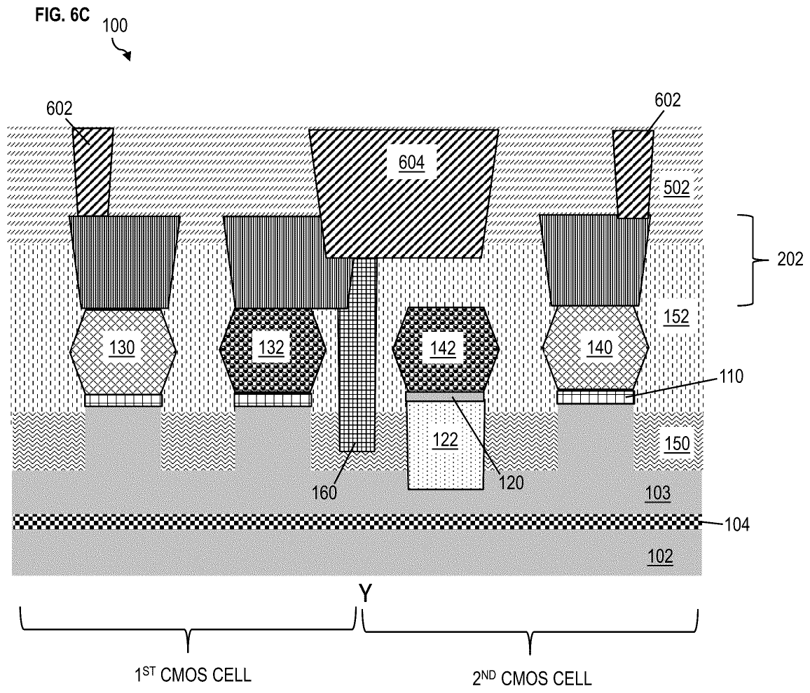

FIGS. 6A, 6B, and 6C depict the IC 100 after back-end-of-line (BEOL) processing. Conductive vias are formed in the ILD material 502. For example, conductive vias 602 are formed on top of the metal source/drain contacts 202 to electrically and physically contact source/drain epitaxial regions 130, 132, 140, 141. A local interconnect 604 is formed over the source/drain epitaxial region 142 so as not to be in physical and electrical contact with the source/drain epitaxial region 142. The local interconnect 604 is formed on one of the source/drain contacts 202, on the gate cut region 160, and in the ILD material 152 directly over the source/drain epitaxial region 142 (which will have a direct backside contact). The solid filled gate spacers 118 separate the sides of the local interconnect 604 from the adjacent gate structures 116, thereby preventing the potential of a short circuit if an airgap spacer were present and if the local interconnect landed off target such that its conductive material unintentionally filled the airgap. Moreover, even is the local interconnect 604 were misaligned, the solid filled gate spacer 118 avoids a short circuit with the gate structure 116 as seen in FIG. 6B.

The local interconnect 604 wires the source/drain 132 from 1^{st} CMOS cell through the cell boundary to the 2^{nd} CMOS cell. The conductive vias 602 and the local interconnect 604 are formed of conductive material such as a metal. Example conductive materials may include Co, Ru, copper, aluminum, tungsten, gold, metal alloys, etc.

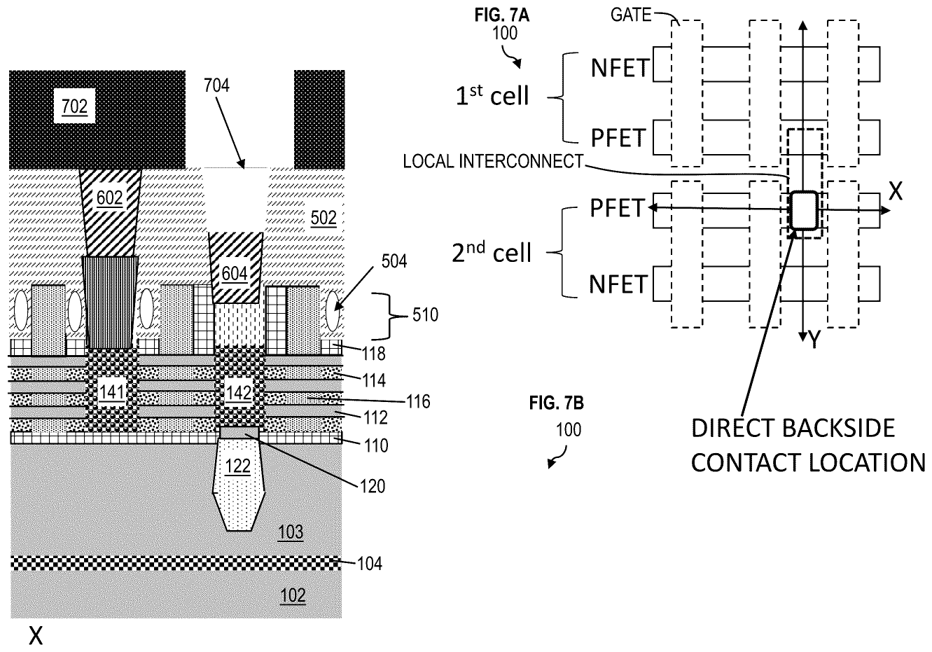

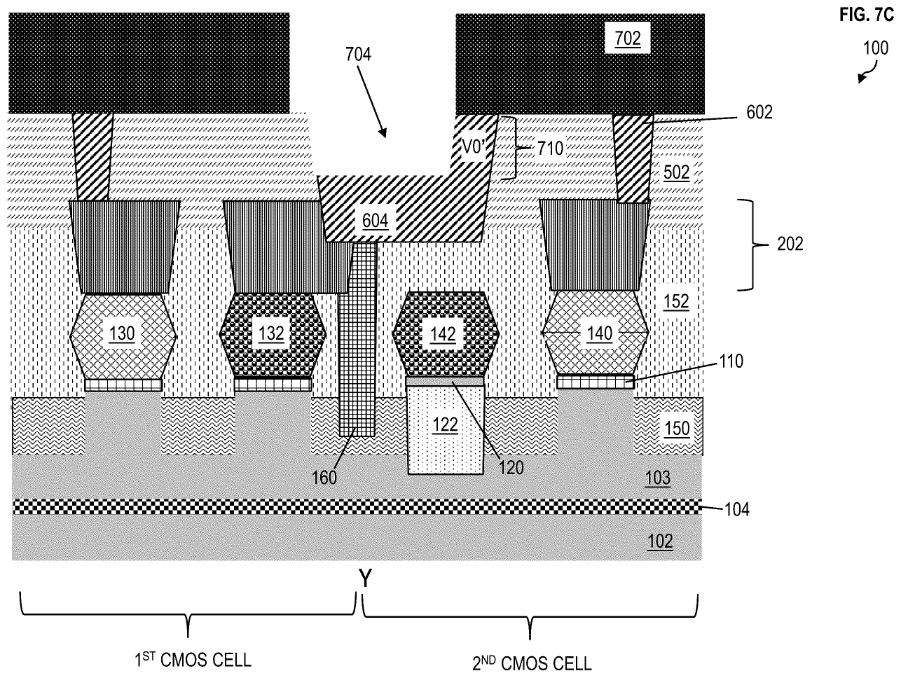

FIGS. 7A, 7B, and 7C depict the IC 100 after removal of unwanted conductive material. A mask layer 702 is deposited and etched. The mask layer 702 may be an OPL and/or any suitable material or combination of materials. An anisotropic etch may be utilized to etch the mask layer 702. Using the patterned mask layer 702, etching is performed to recess portions of the local interconnect 604, resulting in an asymmetric conductive via 710 (e.g., V0′) on top of the recessed local interconnect 604 and a trench 704.

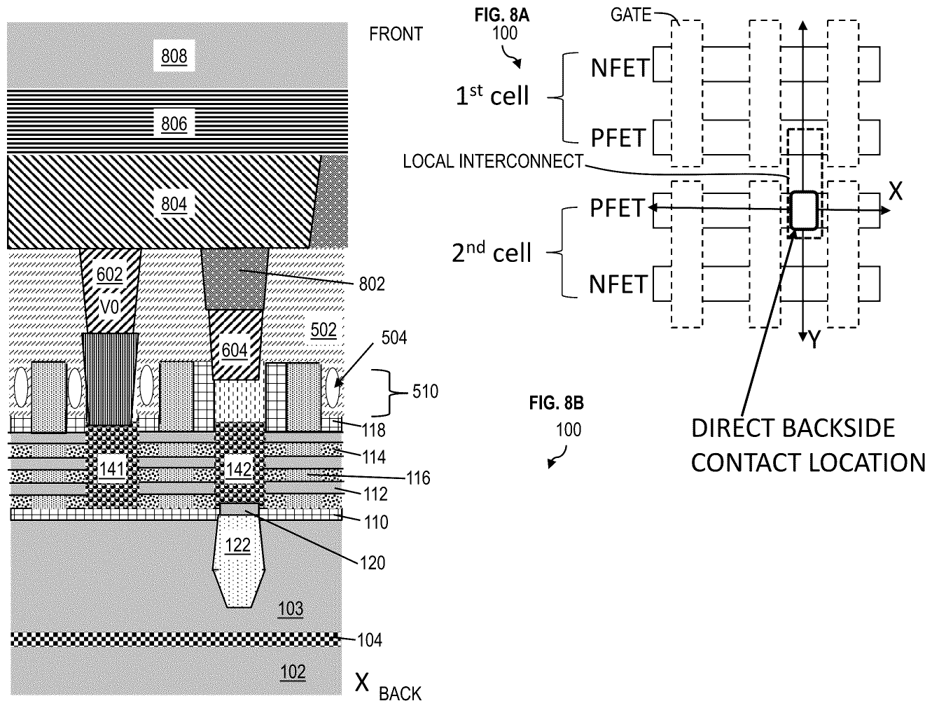

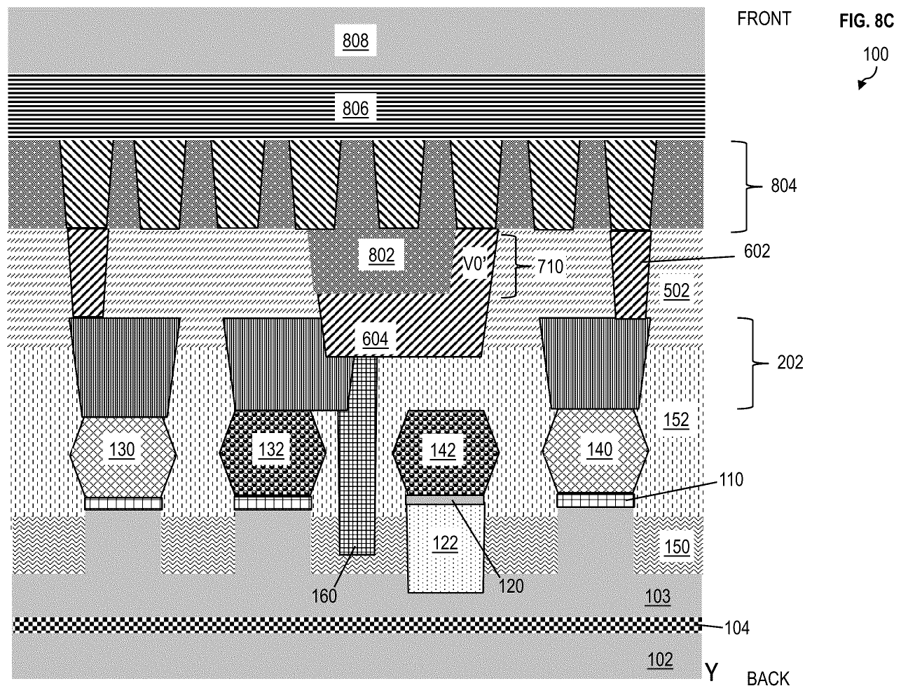

FIGS. 8A, 8B, and 8C depict the IC 100 after forming additional BEOL layers. The mask layer 702 is removed (e.g., by ashing the OPL), ILD material 802 is deposited which fills the trench 704, and metal lines 804 (M1 lines) are formed in the ILD material 802. One of the metal lines 804 is in direct contact with the asymmetric conductive via 710 (V0′), where the conductive via 710 is in direct contact with the local interconnect 604, and where the local interconnect 604 is in direct contact with the metal source/drain contact 202 connected to the source/drain epitaxial region 132 in the first CMOS cell. By this way, a S/D region from the 1^{st} CMOS cell is wired to access M1 tracks over a 2^{nd} CMOS cell. This provides flexibility for routing options. The space above the source/drain epitaxial region 142 is efficiently utilized for routing the local interconnect 604 between the first and second CMOS cells. Additional BEOL layers 806 are formed, and a carrier wafer 808 is bonded to the BEOL layers 806.

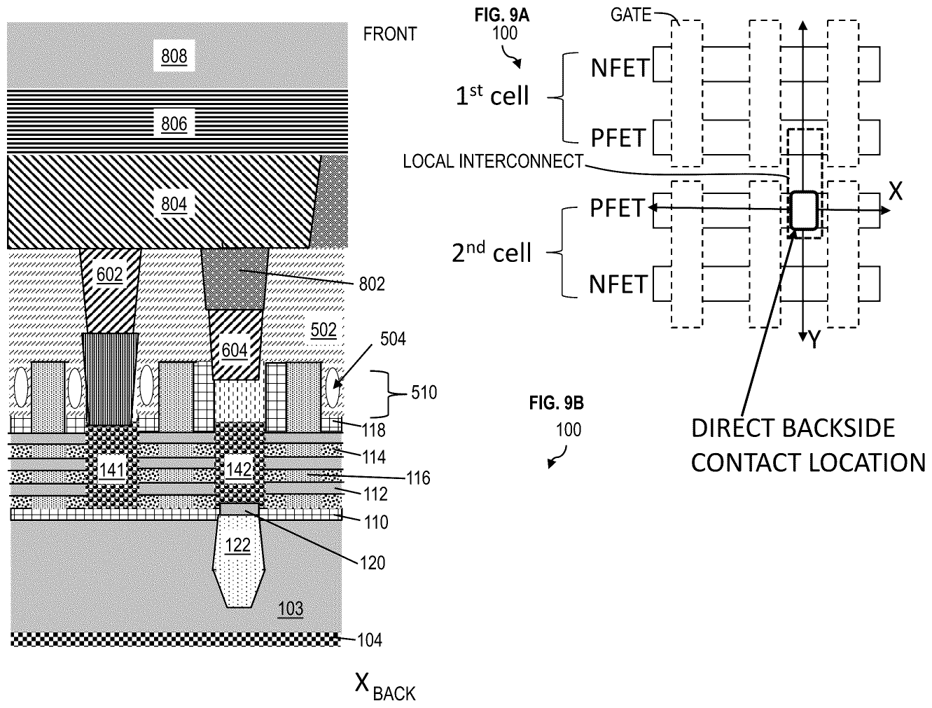

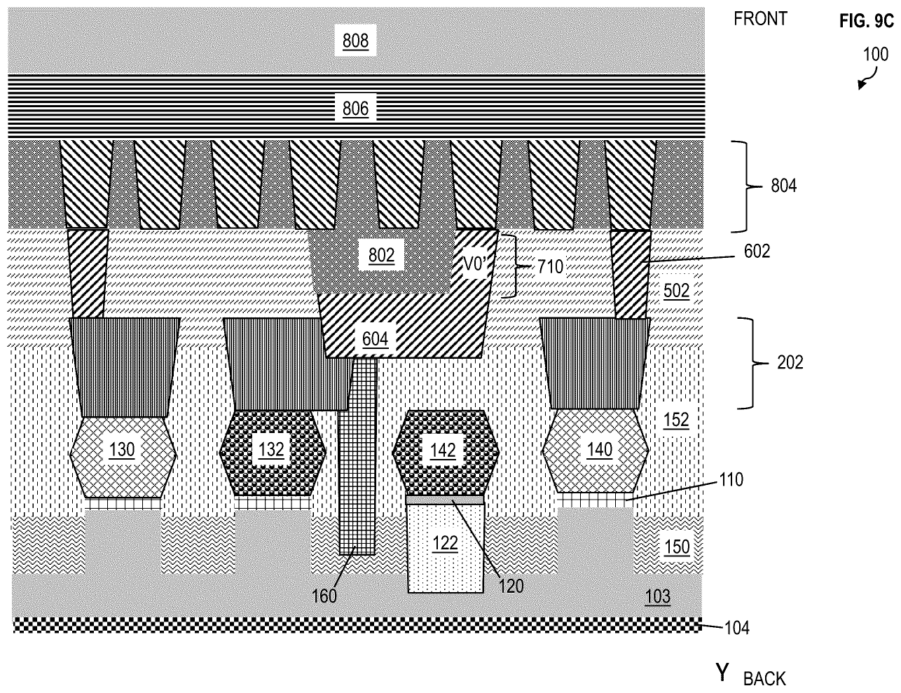

FIGS. 9A, 9B, and 9C depict the IC 100 after wafer flip and substrate removal. The front side is the top and the backside refers to the bottom. The following fabrication processes are performed with the backside up and positioned for processing, as understood by one of ordinary skill in the art. However, the front side and backside of the wafer are not flipped in the figures so as not to disorient the reader, although it should be appreciated that the wafer is flipped, and the fabrication is now being performed to the backside. The substrate 102 has been removed, with etching stopping on the etch stop layer 104. The substrate can be removed by a combination of wafer grinding, CMP, and dry/wet etch process. The final stage of the substrate removal process should be selective to etch stop layer, such as ammonia based Si wet etch.

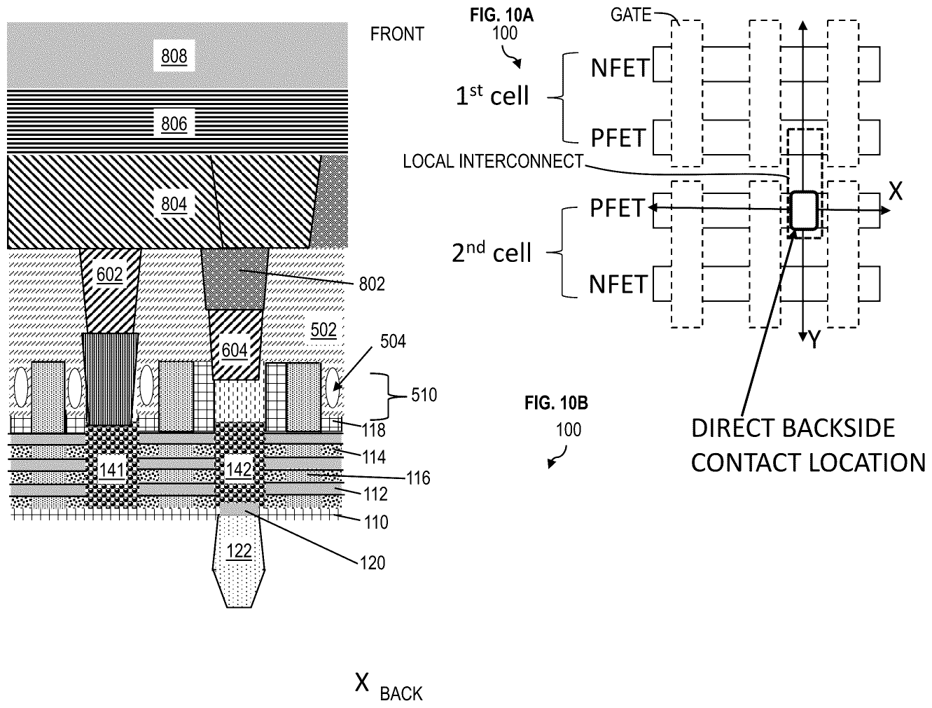

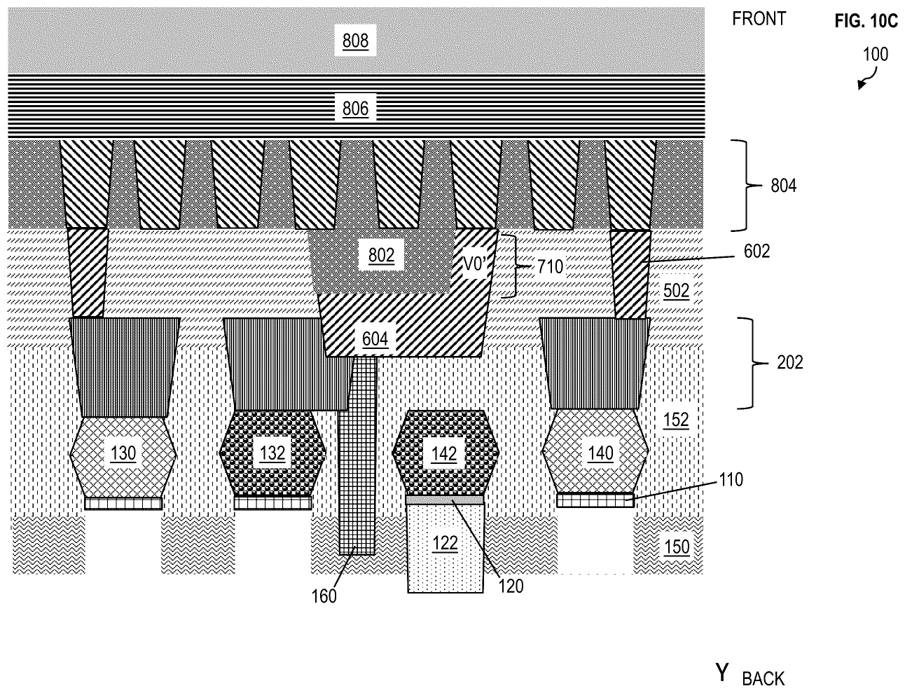

FIGS. 10A, 10B, and 10C depict the IC 100 after etch stop layer removal. The etch stop layer 104 is removed and the substrate 103 is removed. The sacrificial placeholder 122 is exposed for further processing.

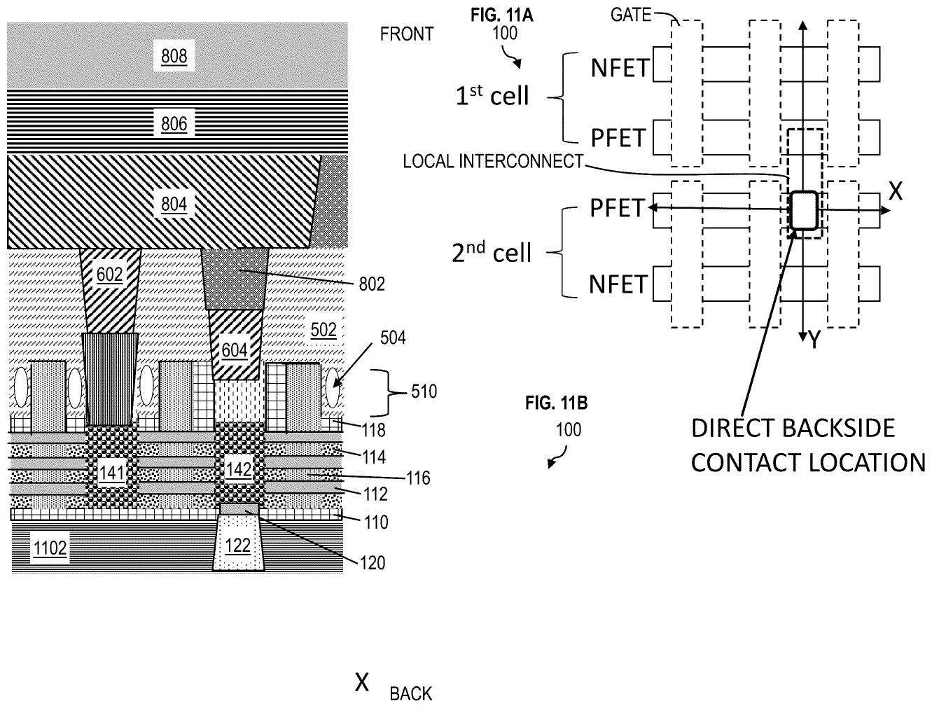

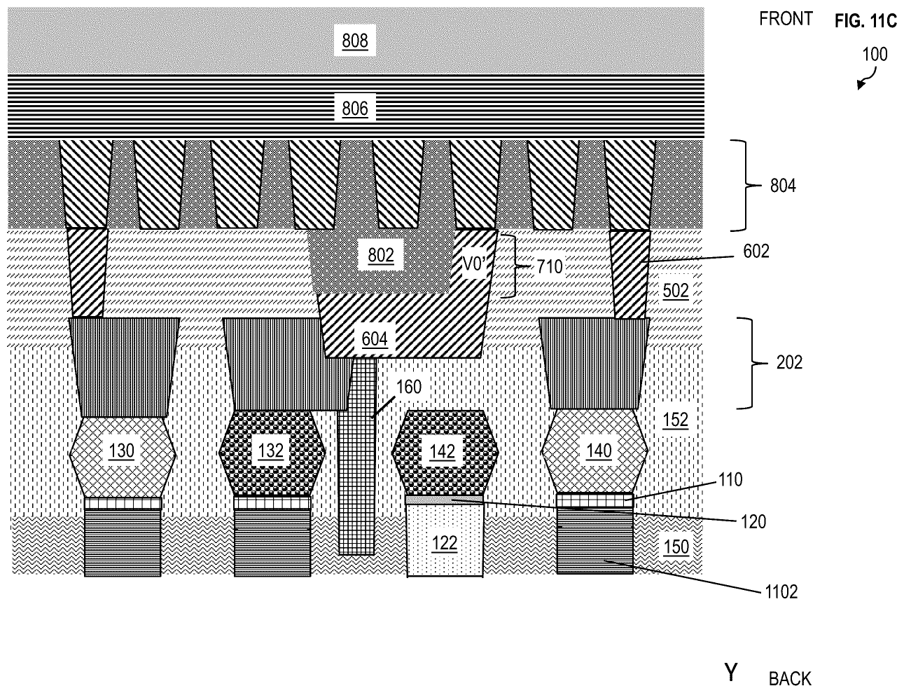

FIGS. 11A, 11B, and 11C depict the IC 100 after backside ILD deposition. The backside ILD material 1102 is deposited. The ILD material 1102 can be SiO₂, a nitride material such as SiN, SiOC, SiBCN, etc., or low k dielectrics with k value <4. CMP is performed which removes a portion of the sacrificial placeholder 122.

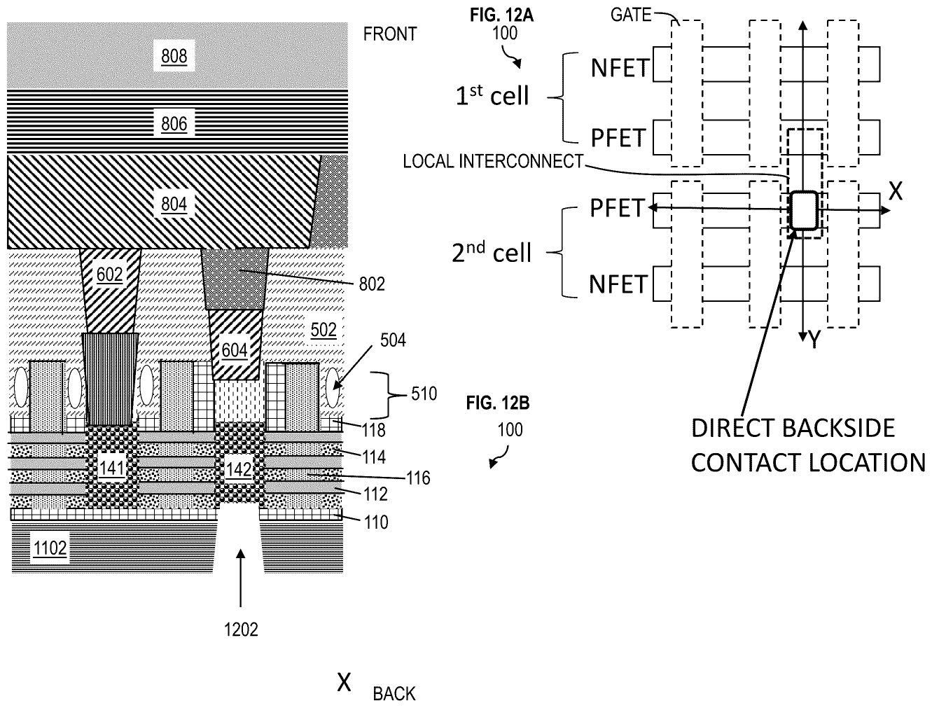

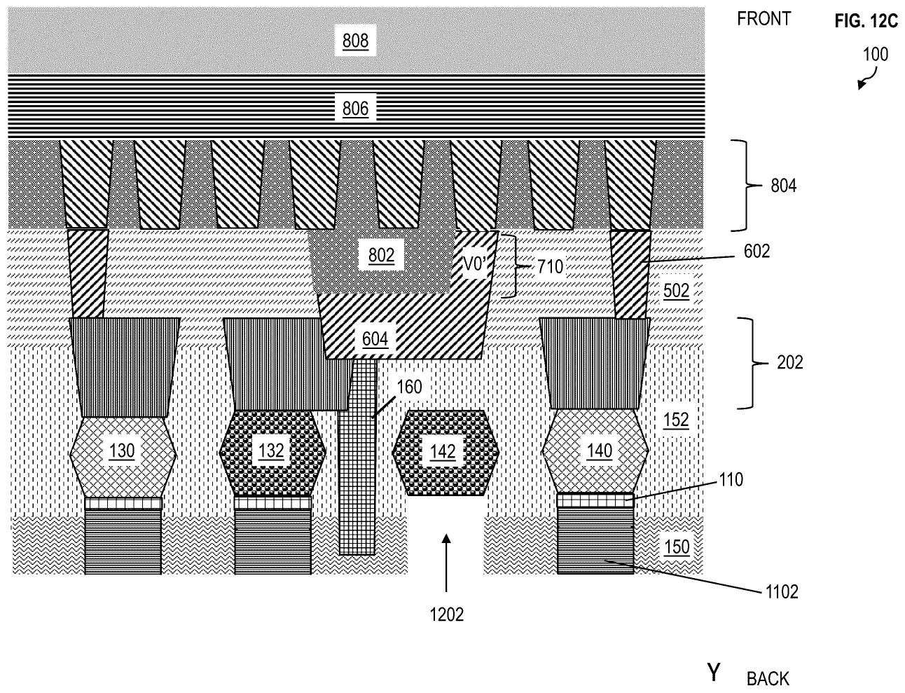

FIGS. 12A, 12B, and 12C depict the IC 100 after sacrificial placeholder removal and a backside contact pre-clean. The sacrificial placeholder 122 and buffer layer 120 are removed, leaving a cavity 1202. A selective reactive ion etch (RIE) or selective wet etch may be utilized to remove the sacrificial placeholder 122 and buffer layer 120. A cleaning process is performed on the backside in preparation for the backside contact formation.

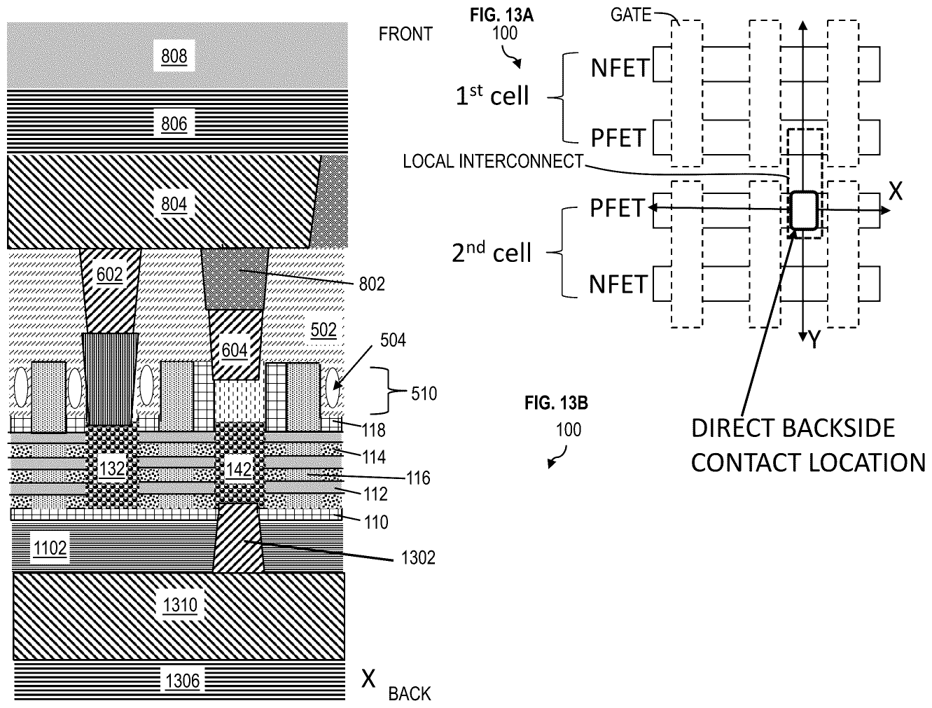

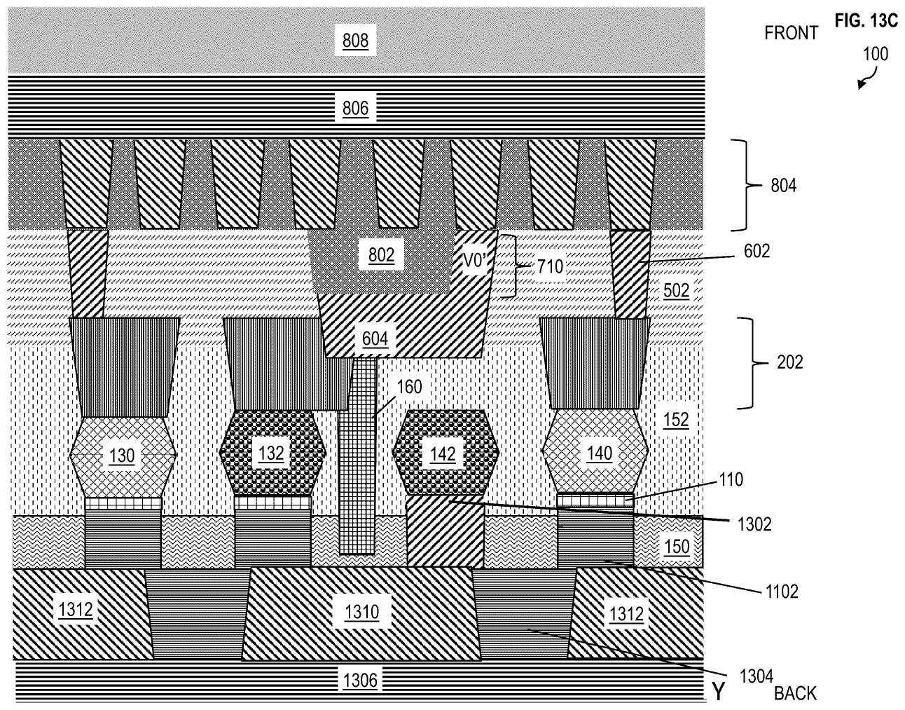

FIGS. 13A, 13B, and 13C depict the IC 100 after backside contact metallization. A backside contact 1302 is formed in the cavity 1202 so as to physically and electrically contact the source/drain epitaxial region 142. The backside contact 1302 may be formed of a silicide and metal. Backside power rails 1310 and 1312 are formed, and a backside power distribution network (BSPDN) 1306 is formed. Backside power rail 1310 connects to the backside contact 1302. Backside power rails 1310 and 1312 are formed to connect to respective backside contacts, and the BSPDN 1306 connects to various backside power rails, as understood by one or ordinary skill in the art.

The ILD material can be SiO₂, SiN, a low-k dielectric material or an ultralow-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultralow k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultralow-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low k dielectric films can be formed by hydrolysis and polycondensation of an alkoxide(s) such as tetraetehoxysilane (TEOS).

Although examples illustrate a single backside contact 1302 connected to a PFET, it should be appreciated that an IC has numerous backside contacts 1302 connected to numerous PFETs and NFETs. There can be hundreds, thousands, or millions of transistors in an IC, each having their own contacts including backside contacts 1302.

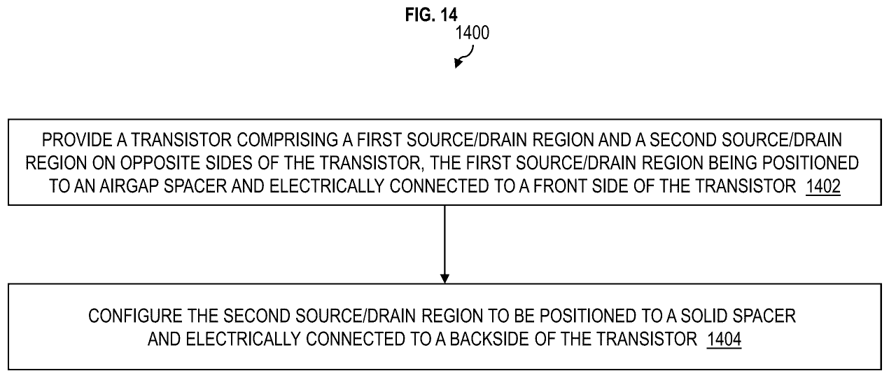

FIG. 14 is a flowchart of a computer-implemented method of forming an airgap spacer and local interconnect configuration with a direct backside contact according to one or more embodiments. At block 1402, the method 1400 includes providing a transistor (e.g., in the second CMOS cell) having a first source/drain region (e.g., source/drain epitaxial regions 141) and a second source/drain region (e.g., source/drain epitaxial regions 142) on opposite sides of the transistor, the first source/drain region (e.g., source/drain epitaxial regions 141) being positioned to an airgap spacer 510 and electrically connected to a front side of the transistor. At block 1404, the method 1400 includes configuring the second source/drain region (e.g., source/drain epitaxial regions 142) to be positioned to a solid spacer (e.g., gate spacer 118) and electrically connected to a backside of the transistor.

A backside contact 1302 is coupled to the second source/drain region (e.g., source/drain epitaxial region 142). A local interconnect 604 is adjacent to the solid spacer (e.g., gate spacer 118). A local interconnect 604 is over the second source/drain region (e.g., source/drain epitaxial region 142) and a backside contact 1302, the backside contact being coupled to the second source/drain region (e.g., source/drain epitaxial region 142).

A local interconnect 604 is adjacent to the solid spacer (e.g., gate spacer 118), and a metal line 804 (M1 line) is over and separated from the local interconnect 604 by interlayer dielectric material (e.g., ILD 802). Another transistor (e.g., in the first CMOS cell) comprises another source/drain region (e.g., source/drain epitaxial region 132) coupled to a local interconnect 604, the local interconnect 604 being electrically connected to a metal line 804 that crosses over a cell (e.g., the second CMOS cell) containing the transistor.

Another transistor (e.g., in the first CMOS cell) having another source/drain region (e.g., source/drain epitaxial region 132) coupled to a local interconnect 604, the local interconnect being electrically connected to a metal line that crosses over a cell (e.g., the second CMOS cell) containing the transistor. The transistor in the second CMOS cell is free of an electrical connection to the same metal line.

A local interconnect 604 is adjacent to the solid spacer (e.g., gate spacer 118) and over the second source/drain region (e.g., source/drain epitaxial region 142). A conductive via 602 (V0) is over the first source/drain region (e.g., source/drain epitaxial region 141) and has a symmetric shape. A conductive via 710 (V0′) is over the local interconnect 604 and the second source/drain region (e.g., source/drain epitaxial region 142) and has an asymmetric shape.

The transistor comprises a gate structure 116, the first source/drain region (e.g., source/drain epitaxial region 141) and the second source/drain region (e.g., source/drain epitaxial region 142) being positioned on opposing sides of the gate structure.

The transistor comprises a gate structure 116, the airgap spacer 510 and the solid spacer (e.g., gate spacer 118) being positioned on opposing sides of the gate structure 116.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a transistor comprising a first source/drain region and a second source/drain region on opposite sides of the transistor, the first source/drain region being below an airgap spacer and electrically connected to a front side of the transistor, the second source/drain region being adjacent to a solid spacer and electrically connected to a backside of the transistor, wherein the front side is above the transistor and the backside is below the transistor.

2. The semiconductor structure of claim 1, wherein a backside contact is coupled to the second source/drain region.

3. The semiconductor structure of claim 1, wherein a local interconnect is adjacent to the solid spacer.

4. The semiconductor structure of claim 1, wherein a local interconnect is over the second source/drain region and a backside contact, the backside contact being coupled to the second source/drain region.

5. The semiconductor structure of claim 1, wherein:
a local interconnect is adjacent to the solid spacer; and
a metal line is over and separated from the local interconnect by interlayer dielectric material.

6. The semiconductor structure of claim 1, further comprising another transistor having another source/drain region coupled to a local interconnect, the local interconnect being electrically connected to a metal line that crosses over a cell containing the transistor.

7. The semiconductor structure of claim 1, further comprising another transistor having another source/drain region coupled to a local interconnect, the local interconnect being electrically connected to a metal line that crosses over a cell containing the transistor; and
wherein the transistor is free of an electrical connection to the metal line.

8. The semiconductor structure of claim 1, wherein:
a local interconnect is adjacent to the solid spacer and over the second source/drain region;
a conductive via over the first source/drain region having a symmetric shape; and
another conductive via over the local interconnect and the second source/drain region having an asymmetric shape.

9. The semiconductor structure of claim 1, wherein the transistor comprises a gate structure, the first source/drain region and the second source/drain region being positioned on opposing sides of the gate structure.

10. The semiconductor structure of claim 1, wherein the transistor comprises a gate structure, the airgap spacer and the solid spacer being positioned on opposing sides of the gate structure.

11. A method comprising:
providing a transistor comprising a first source/drain region and a second source/drain region on opposite sides of the transistor, the first source/drain region being below an airgap spacer and electrically connected to a front side of the transistor; and
configuring the second source/drain region to be adjacent to a solid spacer and electrically connected to a backside of the transistor, wherein the front side is above the transistor and the backside is below the transistor.

12. The method of claim 11, wherein a backside contact is coupled to the second source/drain region.

13. The method of claim 11, wherein a local interconnect is adjacent to the solid spacer.

14. The method of claim 11, wherein a local interconnect is over the second source/drain region and a backside contact, the backside contact being coupled to the second source/drain region.

15. The method of claim 11, wherein:
a local interconnect is adjacent to the solid spacer; and
a metal line is over and separated from the local interconnect by interlayer dielectric material.

16. The method of claim 11, wherein another transistor comprises another source/drain region coupled to a local interconnect, the local interconnect being electrically connected to a metal line that crosses over a cell containing the transistor.

17. The method of claim 11, wherein another transistor comprises another source/drain region coupled to local interconnect, the local interconnect being electrically connected to a metal line that crosses over a cell containing the transistor; and
wherein the transistor is free of an electrical connection to the metal line.

18. The method of claim 11, wherein:
a local interconnect is adjacent to the solid spacer and over the second source/drain region;
a conductive via over the first source/drain region having a symmetric shape; and
another conductive via over the local interconnect and the second source/drain region having an asymmetric shape.

19. The method of claim 11, wherein the transistor comprises a gate structure, the first source/drain region and the second source/drain region being positioned on opposing sides of the gate structure.

20. The method of claim 11, wherein the transistor comprises a gate structure, the airgap spacer and the solid spacer being positioned on opposing sides of the gate structure.
